(19) United States
(12) Patent Application Publication
(10) Pub. No.: US 2013/0087873 A1
(43) Pub. Date: Apr. 11, 2013

(54) SOLID-STATE IMAGING DEVICE AND METHOD FOR MANUFACTURING SOLID-STATE IMAGING DEVICE

(71) Applicant: Hirokazu SEKINE, Kanagawa-ken (JP)

(72) Inventor: Hirokazu SEKINE, Kanagawa-ken (JP)

(73) Assignee: Kabushiki Kaisha Toshiba, Tokyo (JP)

(21) Appl. No.: 13/417,594

(22) Filed: Mar. 12, 2012

(30) Foreign Application Priority Data
Oct. 7, 2011 (JP) 2011-222899

(51) Int. Cl. H01L 31/0232; H01L 31/18

(52) U.S. Cl. 257/432; 438/69; 257/E31.127

(57) ABSTRACT

Certain embodiments provide a solid-state imaging device including a semiconductor substrate, a reflector, and an external electrode. The semiconductor substrate has a photosensitive region including a photodiode on the surface thereof and the back surface thereof is polished by mirror finish. The reflector is formed on the back surface of the semiconductor substrate and reflects infrared rays incident on the photosensitive region. The external electrode is electrically connected to the photosensitive region.

### CROSS REFERENCE TO RELATED APPLICATIONS

This application is based upon and claims the benefit of priority from the prior Japanese Patent Application No. 2011-222899 filed in Japan on Oct. 7, 2011; the entire contents of which are incorporated herein by reference.

### FIELD

Embodiments described herein relate generally to a solid-state imaging device and method for manufacturing a solid-state imaging device.

### BACKGROUND

A conventional solid-state imaging device receiving infrared rays (hereinafter, referred to as a conventional infrared ray sensor) mainly receives infrared rays in a deeper portion of a semiconductor substrate to make a photoelectric conversion and collects charges generated thereby in a photodiode formed on the front surface of the semiconductor substrate. However, charges are mainly generated in a deeper portion of the semiconductor substrate and thus, charges generated by infrared rays being received disappear for the most part before reaching the photodiode due to recombination. Therefore, even if infrared rays are received, it is difficult to collect charges generated thereby in a photodiode. This causes degradation in receiving sensitivity of an infrared sensor.

Further, generated carriers diffuse isotropically because no electric field is applied to a deeper portion of the semiconductor substrate. Therefore, charges generated by infrared rays being received in the semiconductor substrate do not reach a predetermined photodiode and instead are collected by other photodiodes in the vicinity of the predetermined photodiode. This causes degradation in resolution of an infrared sensor.

### BRIEF DESCRIPTION OF THE DRAWINGS

FIG. 1 is a sectional view showing a solid-state imaging device according to a first embodiment;

FIG. 2 is a plan view when a portion of a semiconductor substrate applied to the solid-state imaging device in FIG. 1 is viewed from a back surface;

FIG. 3 shows a sectional view illustrating a method for manufacturing the solid-state imaging device according to the first embodiment and shows a process of fixing a transparent member in a wafer shape onto a semiconductor wafer;

FIG. 4 shows a sectional view illustrating the method for manufacturing the solid-state imaging device according to the first embodiment and shows a process of thinning the semiconductor wafer;

FIG. 5 shows a sectional view illustrating the method for manufacturing the solid-state imaging device according to the first embodiment and shows a process of forming a through hole in the thinned semiconductor wafer;

FIG. 6 shows a sectional view illustrating the method for manufacturing the solid-state imaging device according to the first embodiment and shows a process of forming a reflector and a wire on the back surface of the semiconductor wafer;

FIG. 7 shows a sectional view illustrating the method for manufacturing the solid-state imaging device according to the first embodiment and shows a process of forming an external electrode;

FIG. 8 shows a sectional view illustrating the method for manufacturing the solid-state imaging device according to the first embodiment and shows a process of dividing into a plurality of solid-state imaging devices;

FIG. 9 is a sectional view enlarging and showing a portion of the semiconductor substrate applied to the solid-state imaging device according to the first embodiment;

FIG. 10 is a graph showing a relationship between the wavelength of light shone on silicon and the absorption coefficient of light by silicon;

FIG. 11 is a graph showing the relationship between the wavelength of light shone on silicon and the depth where the intensity of the light is attenuated to 1/e;

FIG. 12 is a graph comparing and showing relative sensitivity of an actually manufactured solid-state imaging device and relative sensitivity of the solid-state imaging device based on a simulation;

FIG. 13 is a simulation result of the relationship between the wavelength of light incident on a conventional solid-state imaging device when the diffusion length of carriers is 30 μm and the relative sensitivity by thickness of the semiconductor substrate;

FIG. 14 is a simulation result of the relationship between the wavelength of light incident on the conventional solid-state imaging device when the diffusion length of carriers is 20 μm and the relative sensitivity by thickness of the semiconductor substrate;

FIG. 15 is a simulation result of the relationship between the wavelength of light incident on the solid-state imaging device according to the present embodiment when the diffusion length of carriers is 30 μm and the relative sensitivity by thickness of the semiconductor substrate;

FIG. 16 is a simulation result of the relationship between the wavelength of light incident on the solid-state imaging device according to the present embodiment when the diffusion length of carriers is 20 μm and the relative sensitivity by thickness of the semiconductor substrate;

FIG. 17 is a graph comparing and showing the relative sensitivity of the conventional solid-state imaging device and the relative sensitivity of the solid-state imaging device according to the present embodiment when the diffusion length is 30 μm;

FIG. 18 is a graph comparing and showing the relative sensitivity of the conventional solid-state imaging device and the relative sensitivity of the solid-state imaging device according to the present embodiment when the diffusion length is 20 μm;

FIG. 19 is a sectional view showing a solid-state imaging device according to a second embodiment and corresponding to FIG. 1;

FIG. 20 is a sectional view illustrating the method for manufacturing the solid-state imaging device according to the second embodiment and shows a process of fixing a transparent member in the wafer shape onto the semiconductor wafer; and

FIG. 21 is a graph showing the relationship between the relative sensitivity and the thickness of the semiconductor substrate in the solid-state imaging device according to the present embodiment when the diffusion length is 30 μm by wavelength of light incident on the device.

### DETAILED DESCRIPTION

Certain embodiments provide a solid-state imaging device including a semiconductor substrate, a reflector, and an external electrode. The semiconductor substrate has a photosensitive region including a photodiode on the front surface thereof and the back surface polished by mirror finish. The reflector is formed on the back surface of the semiconductor substrate and reflects infrared rays incident on the photosensitive region. The external electrode is electrically connected to the photosensitive region.

Certain embodiments provide method for manufacturing a solid-state imaging device, the method including thinning a semiconductor substrate from a back surface and polishing the back surface of the semiconductor substrate by mirror finish, forming a reflector that reflects infrared rays, and forming an external electrode. The semiconductor substrate has a photosensitive region including a photodiode on a front surface. The reflector that reflects infrared rays incident on the photosensitive region is formed on the back surface of the thinned semiconductor substrate having the back surface polished by mirror finish. The external electrode is formed so as to be electrically connected to the photosensitive region.

Solid-state imaging devices and methods for manufacturing a solid-state imaging device according to embodiments will be described below in detail with reference to the drawings. The solid-state imaging device described below is an infrared sensor that receives infrared rays.

### First Embodiment

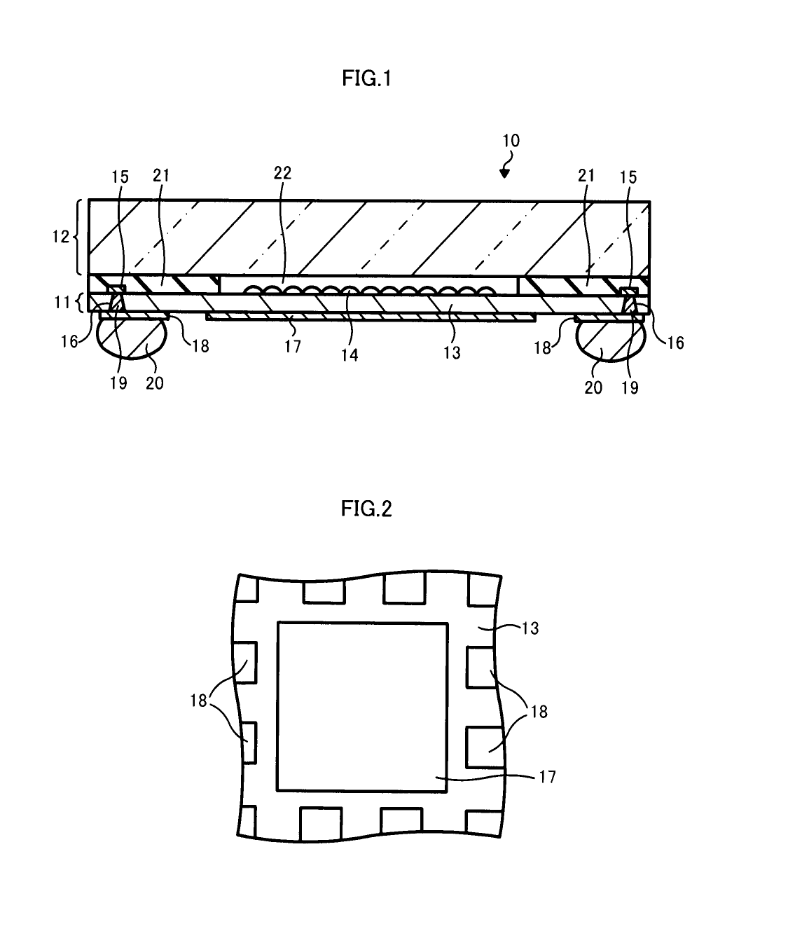

FIG. 1 is a sectional view showing a solid-state imaging device according to the first embodiment. A solid-state imaging device 10 shown in FIG. 1 includes an infrared sensor substrate 11 and a transparent member 12.

The infrared sensor substrate 11 includes a thinned semiconductor substrate 13. The semiconductor substrate 13 is, for example, an n-type silicon substrate and the back surface thereof is polished by mirror finish.

The front surface of the semiconductor substrate 13 has a photosensitive region (not shown) formed thereon. The photosensitive region is, for example, a region in which a plurality of n-type photodiodes (not shown) and a plurality of microlenses 14 are arrayed in a lattice shape. The plurality of photodiodes is formed on the surface of a p-type well layer (not shown) formed on the front surface of the semiconductor substrate 13.

Also on the front surface of the semiconductor substrate 13, a bonding pad 15 electrically connected to the photosensitive region is formed around the photosensitive region, that is, around the plurality of microlenses 14 arrayed in a lattice shape. Then, a through hole 16 passing through the semiconductor substrate 13 is formed below the bonding pad 15.

On the back surface of the semiconductor substrate 13, a reflector 17 that reflects infrared rays and a wire 18 are formed. The reflector 17 is formed on the back surface of the semiconductor substrate 13 so as to contain a region corresponding to the photosensitive region. A plurality of wires 18 is formed on the back surface of the semiconductor substrate 13 around the reflector 17.

FIG. 2 is a plan view of the semiconductor substrate 13 when viewed from the back surface. As shown in FIG. 2, the reflector 17 is formed of, for example, a metal in a quadrangular shape and the reflector 17 described above is formed so as to contain, as described above, a region corresponding to the photosensitive region.

The reflector 17 may be formed of any material having a property of reflecting infrared rays and is formed of, for example, a metal such as Cu.

A reflection portion that reflects infrared rays is formed of the polished back surface of the semiconductor substrate 13 and the reflector 17. The reflection portion reflects infrared rays incident on the photosensitive region on the front surface of the semiconductor substrate 13. Therefore, the reflection portion functions as a mirror for infrared rays incident from the front surface of the semiconductor substrate 13.

Further, the reflection portion reflects infrared rays shone on the back surface of the semiconductor substrate 13. Therefore, the reflection portion functions also as a shielding body of infrared rays shone on the back surface of the semiconductor substrate 13.

As shown in FIG. 2, each of the wires 18 is formed of, for example, a metal in a quadrangular shape smaller than the reflector 17 and the plurality of wires 18 is formed, as described above, around the reflector 17.

As shown in FIG. 1, each of the wires 18 is electrically connected to the bonding pad 15 via an electric conductor 19 formed inside the through hole 16.

The wire 18 and the electric conductor 19 may be formed of any conductive material and are formed of, for example, a metal such as Cu. If, for example, the reflector 17, the wire 18, and the electric conductor 19 described above are formed of the same material such as Cu, these portions can be formed by one manufacturing process. Therefore, the reflector 17, the wire 18, and the electric conductor 19 are preferably formed of the same material.

As shown in FIG. 1, an external electrode 20 is formed on each of the plurality of wires 18. Each of the plurality of external electrodes 20 is, for example, a solder ball.

In the infrared sensor substrate 11 described above, the semiconductor substrate 13 is a thinned semiconductor substrate. The thickness of the thinned semiconductor substrate 13 is such a thickness that most infrared rays incident on the photosensitive region are reflected by the reflection portion provided on the back surface of the semiconductor substrate 13. The semiconductor substrate 13 preferably has the thickness in the range of 20 um to 50 um.

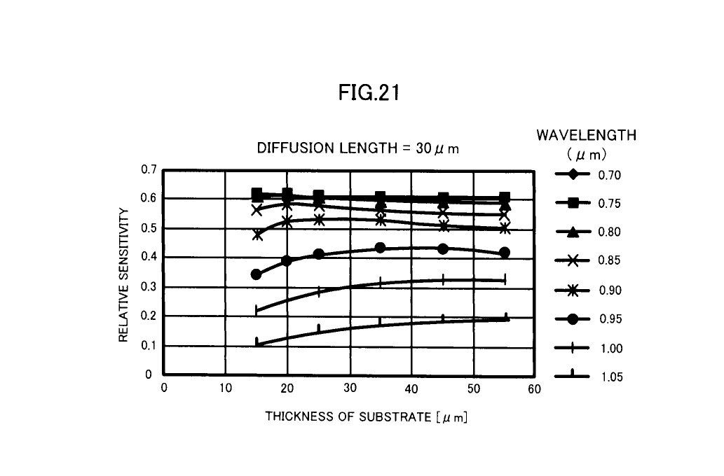

Incidentally, the range of thickness of the semiconductor substrate 13 is based on a simulation result (FIG. 21) of relative sensitivity of the solid-state imaging device described later.

The transparent member 12 is arranged on the infrared sensor substrate 11 having the semiconductor substrate 13 described above and is fixed by an adhesive 21. The adhesive 21 is formed around the photosensitive region, that is, around the plurality of microlenses 14 arrayed in a lattice shape on the front surface of the semiconductor substrate 13. The transparent member 12 is fixed to the semiconductor substrate 13 via the adhesive 21. The transparent member 12 is used to support the thin semiconductor substrate 13. The transparent member 12 is, for example, a glass sheet.

By arranging and fixing the transparent member 12 onto the infrared sensor substrate 11 as described above, a hollow region 22 surrounded by the adhesive 21 and the transparent member 12 is formed on the photosensitive region. Accordingly, a difference of refractive indexes of the hollow region 22 and the microlens 14 can be increased so that condensing properties of incident light to the photodiode by the microlens 14 can be improved.

The structure in which, like the solid-state imaging device 10 described above, the through hole 16 is formed in the semiconductor substrate 13 is generally called a TSV (Through Si Via) and a solid-state imaging device adopting the TSV structure is called a TSV-Chip. Therefore, the above solid-state imaging device 10 is a TSV-Chip.

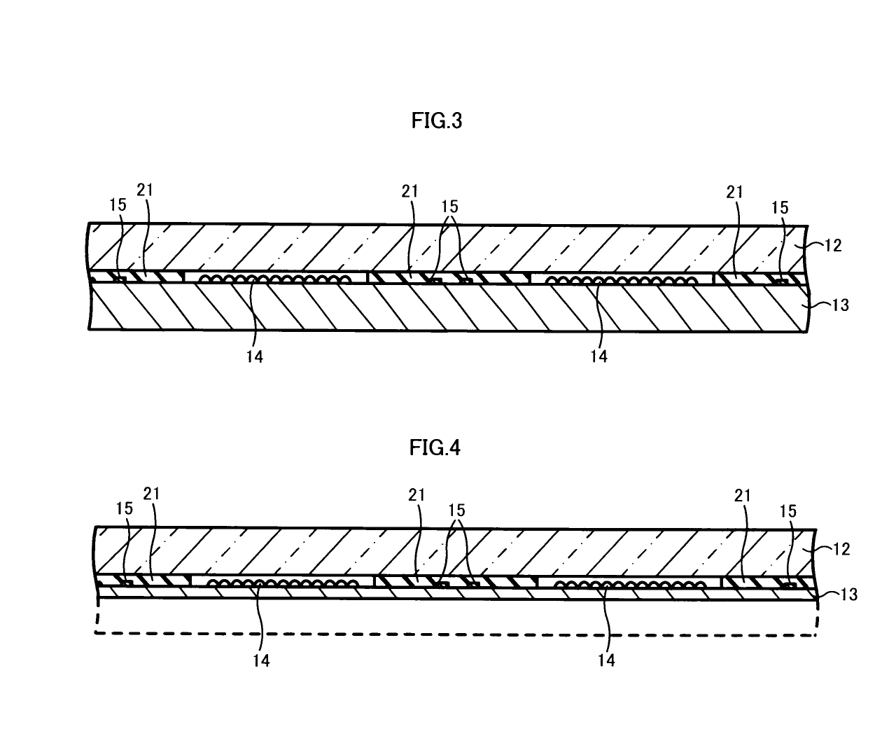

Next, the method for manufacturing a solid-state imaging device according to the first embodiment will be described with reference to FIGS. 3 to 8. FIGS. 3 to 8 are sectional views illustrating the method for manufacturing a solid-state imaging device according to the first embodiment and corresponding to FIG. 1.

The method for manufacturing the solid-state imaging device 10 described below is a method of collectively forming a plurality of the solid-state imaging devices 10 by performing all processes in a wafer state and dividing the plurality of the solid-state imaging devices 10 formed on one wafer into pieces in the end. Therefore, in the description that follows, the above semiconductor substrate 13 is called a semiconductor wafer 13 and the above transparent member 12 is called a wafer 12.

First, as shown in FIG. 3, the adhesive 21 is formed on the semiconductor wafer 13 on which a plurality of photosensitive regions and a plurality of the bonding pads 15 are formed in a lattice shape in a predetermined region. Subsequently, the wafer 12 having transparency is fixed onto the semiconductor wafer 13 via the adhesive 21. The adhesive 21 is formed by, for example, the method of patterning or the like so that the adhesive 21 is formed in each photosensitive region, that is, around the plurality of microlenses 14.

Next, as shown in FIG. 4, the semiconductor wafer 13 is thinned from the back surface and the back surface of the semiconductor wafer 13 is polished by mirror finish. Thinning and polishing are done until the semiconductor wafer 13 is thinned to a predetermined thickness, for example, 20 μm. The semiconductor wafer 13 is thinned by the method of etching, polishing or the like and polishing of the back surface of the semiconductor wafer 13 is done by, for example, the CMP method.

Next, as shown in FIG. 5, the through hole 16 is formed in each predetermined position of the thinned semiconductor wafer 13 whose back surface is polished by mirror finish. Each of the through holes 16 is formed in such a way that at least a portion of the corresponding bonding pad 15 is exposed to the back surface of the semiconductor wafer 13.

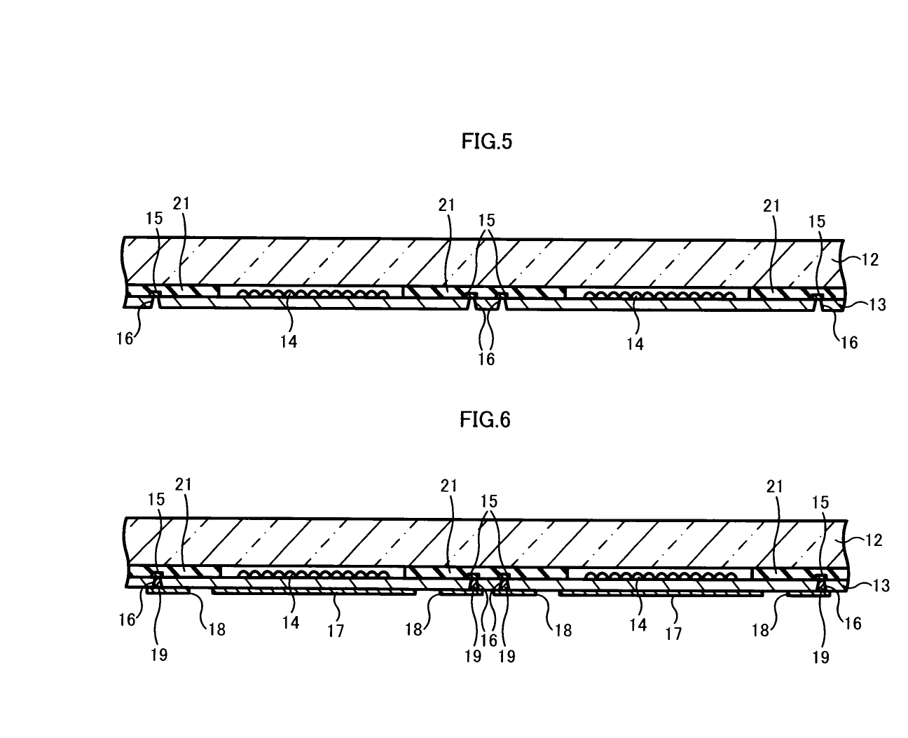

Next, as shown in FIG. 6, the electric conductor 19 is formed inside the through hole 16 of the semiconductor wafer 13 to fill up the through hole 16 and also the reflector 17 and the wire 18 are formed on the back surface of the semiconductor wafer 13. The electric conductor 19 is formed, for example, on the entire surface on the back surface of the semiconductor wafer 13 by depositing a conductor such as a metal. The reflector 17 and the wire 18 are formed by, for example, patterning a metallic film formed, as described above, on the back surface of the semiconductor wafer 13 by deposition.

If the electric conductor 19, the reflector 17, and the wire 18 are formed of the same material, these portions can be formed by one process, reducing the manufacturing process number. However, these portions may be formed of mutually different materials by separate processes.

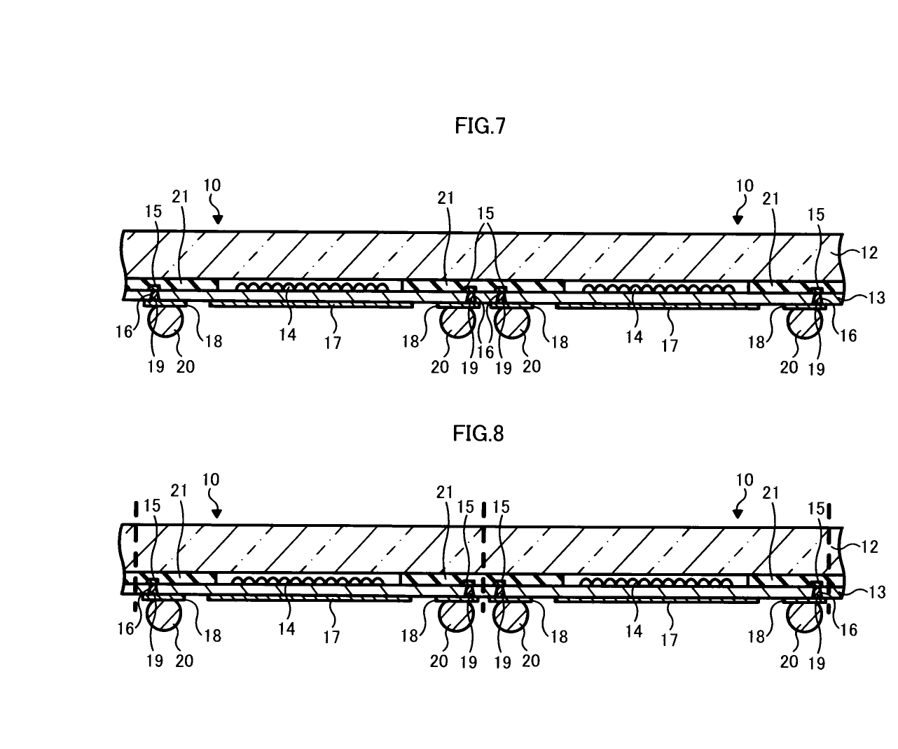

Next, as shown in FIG. 7, for example, a solder ball is formed on each of the wires 18 as the external electrode 20. Accordingly, a plurality of the solid-state imaging devices 10 is formed on one sheet of the semiconductor wafer 13.

Lastly, as shown in FIG. 8, the plurality of the solid-state imaging devices 10 is divided into pieces by dicing between the solid-state imaging devices 10. Accordingly, the plurality of the solid-state imaging devices 10 is formed from one sheet of the semiconductor wafer 13.

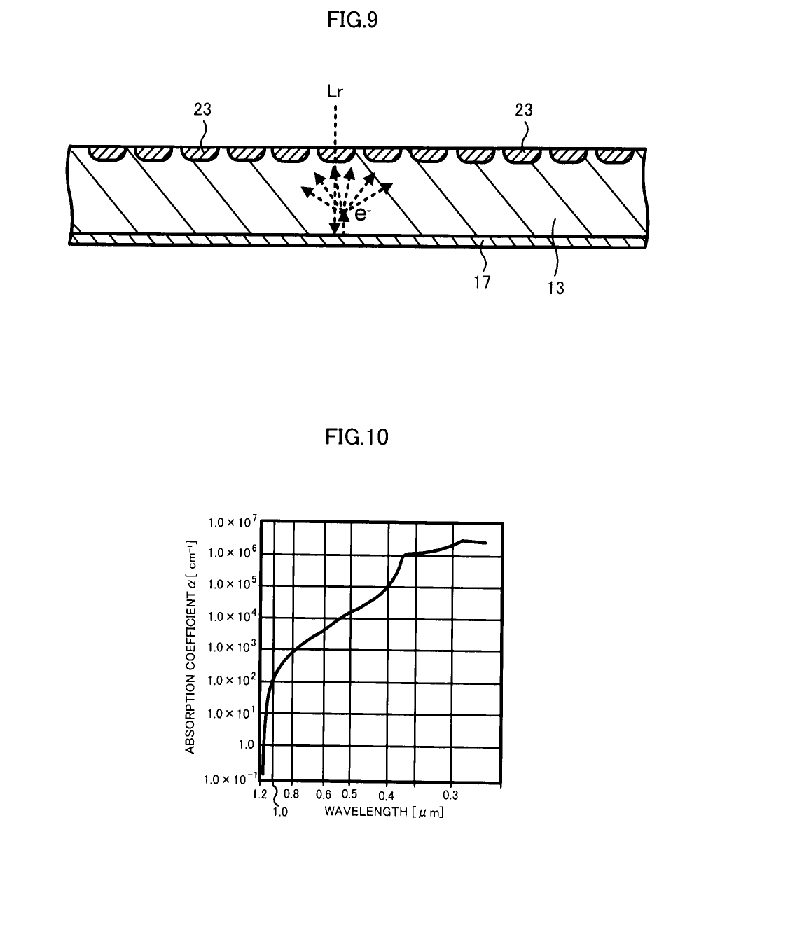

Next, the operation and effect of the solid-state imaging device 10 manufactured as described above will be described with reference to FIGS. 9, 10, and 11.

FIG. 9 is a sectional view enlarging and showing a portion of the semiconductor substrate 13 applied to the solid-state imaging device 10 according to the present embodiment. As shown in FIG. 9, when infrared rays Lr of the wavelength of 0.8 μm or more are incident on the photosensitive region from the front surface of the semiconductor substrate 13, the incident infrared rays Lr penetrate into the semiconductor substrate 13. The infrared rays Lr that have penetrated into the semiconductor substrate 13 are absorbed by the semiconductor substrate 13 as energy and travel into a deeper portion of the semiconductor substrate 13 while radiating carriers (electrons) in accordance with the absorbed amount thereof. That is, when the infrared rays Lr are incident on the semiconductor substrate 13, the infrared rays Lr travel into a deeper portion of the semiconductor substrate 13 while photoelectrically being converted.

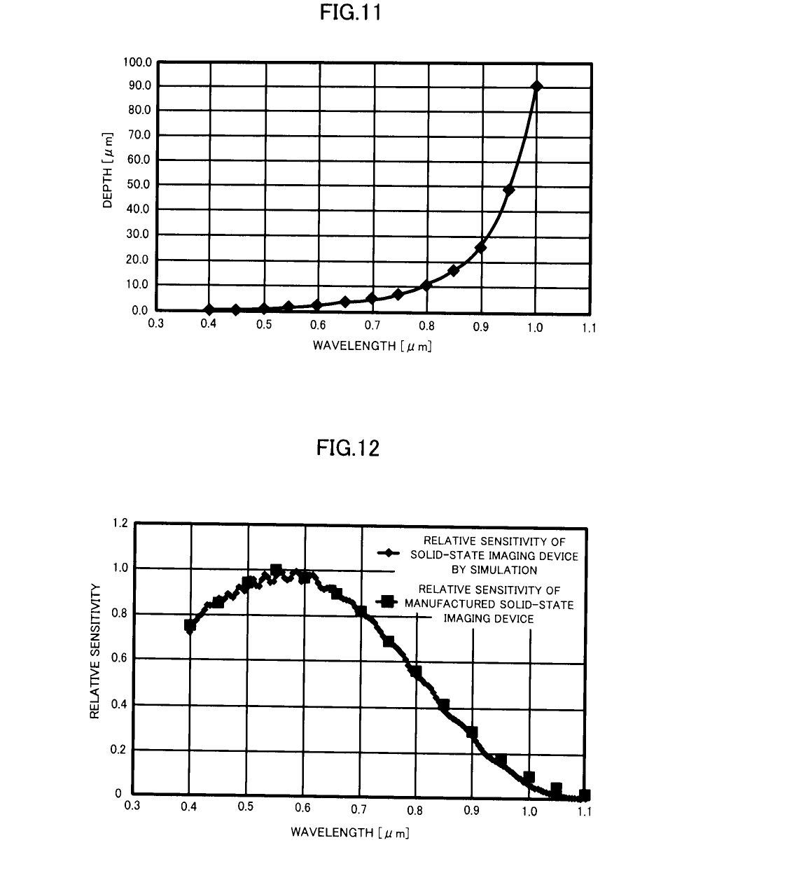

FIG. 10 is a graph showing a relationship between the wavelength of light shone on silicon and the absorption coefficient of light by silicon. FIG. 11 is a graph showing the relationship between the wavelength of light shone on silicon and the depth where the intensity of the light is attenuated to 1/e.

If, as shown in FIG. 10, the semiconductor substrate 13 is silicon, the absorption coefficient of infrared rays of the wavelength of 0.8 μm or more is 1.0×10³ cm⁻¹ or less, which is extremely smaller than the absorption coefficient of visible light of the wavelength of 0.4 μm or more and 0.7 μm or less. Therefore, as shown in FIG. 11, the intensity of visible light is attenuated to 1/e in a shallow region of the depth of 10 μm or less, that is, a surface region of the semiconductor substrate 13. In contrast, the intensity of infrared rays is attenuated to 1/e in a deeper region of the depth of 10 μm or more.

Thus, while photoelectric conversion of visible light occurs mainly in the surface region of the semiconductor substrate 13, photoelectric conversion of infrared rays occurs mainly in a deeper region of the semiconductor substrate 13. Therefore, as shown in FIG. 9, when the infrared rays Lr are incident on the semiconductor substrate 13, only a small portion thereof is photoelectrically converted and the infrared rays LR travel for the most part into a deeper portion of the semiconductor substrate 13.

As shown in FIG. 9, when the infrared rays Lr are incident on the semiconductor substrate 13 made of silicon, as shown in FIGS. 10 and 11, the infrared rays Lr travel in a deeper direction almost without being photoelectrically converted. The semiconductor substrate 13 is thinned to such a thickness that most infrared rays incident on the semiconductor substrate 13 are reflected by the reflection portion including the polished back surface of the semiconductor substrate 13 and the reflector 17, for example, the thickness in the range of 20 μm to 50 μm. Therefore, as shown in FIG. 9, the infrared rays Lr are for the most part reflected by the reflection portion before being photoelectrically converted by the semiconductor substrate 13.

As shown in FIGS. 10 and 11, after being incident on the semiconductor substrate 13 made of silicon, the infrared rays Lr are for the most part photoelectrically converted after a predetermined distance being traveled. Therefore, as shown in FIG. 9, when the infrared rays Lr are incident on the semiconductor substrate 13, the infrared rays Lr are for the most part reflected by the reflection portion and then photoelectrically converted while traveling in the front direction of the semiconductor substrate 13. Accordingly, carriers (electrons) generated by the infrared rays Lr being photoelectrically converted can be generated closer to the front surface of the semiconductor substrate than in the past. Thus, carriers (electrons) can easily be collected by a predetermined photodiode 23 before carriers (electrons) being recombined. Therefore, receiving sensitivity and resolution of infrared rays of a solid-state imaging device can be improved when compared with the past.

Particularly, the improvement of receiving sensitivity of the solid-state imaging device 10 according to the present embodiment is verified by a simulation done by the inventors of the present application. The simulation method and simulation results will be described below.

In the simulation, relative sensitivity S of a solid-state imaging device is calculated by the following method.

First, a charge amount G generated by incident light reaching a deeper portion from the semiconductor surface is determined by using Formula (1).

G(λ,y)=λ×[1−exp(−αy)] Formula (1)

In this formula, y is the depth from the surface of the semiconductor substrate and G represents a charge amount generated up to the depth y from the surface. λ is the wavelength of incident light and α is the absorption coefficient of incident light at wavelength λ. The dependence of the absorption coefficient α on the wavelength λ is shown in FIG. 10.

To discuss spectral characteristics under energy conditions such as correcting an energy difference depending on the wavelength when evaluating spectral characteristics of a solid-state imaging device, the wavelength λ is multiplied at the start of the right side of Formula (1).

A portion of a charge generated in a width Δy of a portion between depths y and y+Δy from the surface of the semiconductor substrate is lost by recombination in the semiconductor substrate before being diffused to a charge storage portion (photodiode) on the surface. If this phenomenon is described by a concept using a diffusion length L of minority carriers, the rate of a charge generated at depth y from the semiconductor surface to reach the surface without being recombined is given by Formula (2):

exp(−y/L) Formula (2)

If carriers reach the deepest portion of the photodiode, carriers will not be recombined. Therefore, in a strict sense, the value of y in the above Formula (2) is y-(depth of photodiode). However, the depth of photodiode is commonly 1 μm or so and thus, the depth of photodiode is ignored.

When the relative sensitivity S of a solid-state imaging device is determined by setting the thickness of the semiconductor substrate of the solid-state imaging device to x, the charge amount generated in a portion between depths y and y+Δy from the surface of the semiconductor substrate is given from Formula (1) as

ΔG(λ,y)=λ×[1−exp(−α(y+Δy))]−λ×[1-exp(−αy)] Form ula (3).

The amount of generated charges reaching the photodiode on the front surface is given from Formulas (2) an (3) as

ΔS(λ,y)=ΔG(λ,y)×exp(−y/L) Formula (4).

The relative sensitivity S of a solid-state imaging device is determined by a value obtained by integrating ΔS in the above Formula (4) from 0 to x. Therefore, the relative sensitivity S of a solid-state imaging device can be calculated from Formula (5):

S(λ,x)=∫ΔG(λ,y)×exp(−y/L)Δy Formula (5)

∫ in Formula (5) has a lower suffix 0 and an upper suffix x.

In a common solid-state imaging device of visible light, a p-type well is formed on an n-type semiconductor substrate and an n-type photodiode is formed on the surface of the well. Comparison of spectral characteristics calculated by the simulation formula and actual spectral characteristics is shown below.

Well diffusion conditions are set as 1200° C.×15 Hr and the change point of well impurities is the position of 5.5 μm from the surface of the semiconductor substrate. A charge generated in a deeper portion than 5.5 μm from the surface of the semiconductor substrate cannot overcome a potential barrier at the well bottom and does not reach the front surface. That is, a solid-state imaging device whose change point of well impurities is 5.5 μm from the surface of the semiconductor substrate is similar to a solid-state imaging device in which the thickness of the semiconductor substrate is 5.5 μm.

Normally, microscopic defects are introduced into the semiconductor substrate for gettering. Thus, the diffusion length L of minority carriers has a value 20 μm to 40 μm or so. The diffusion length of this portion is sufficiently long in a structure in which a p-type well is formed on the surface.

FIG. 12 is a comparison diagram of graph of measured values of spectral characteristics when the well change point is 5.5 μm and simulation values of spectral characteristics of relative sensitivity after being normalized with respect to peak values. In the simulation, x in Formula (5) is set as x=5.5 μm and the diffusion length L as L=40 μm.

As shown in FIG. 12, sensitivity of actually manufactured solid-state imaging devices and simulation results roughly match. The inventors of the present application use Formula (5) that closely matches sensitivity of actually manufactured solid-state imaging devices to calculate relative sensitivity of solid-state imaging devices. In the simulation, the diffusion length of carriers is set to 30 μm or 20 μm and y=20 μm is set.

First, receiving sensitivity of a conventional solid-state imaging device is simulated.

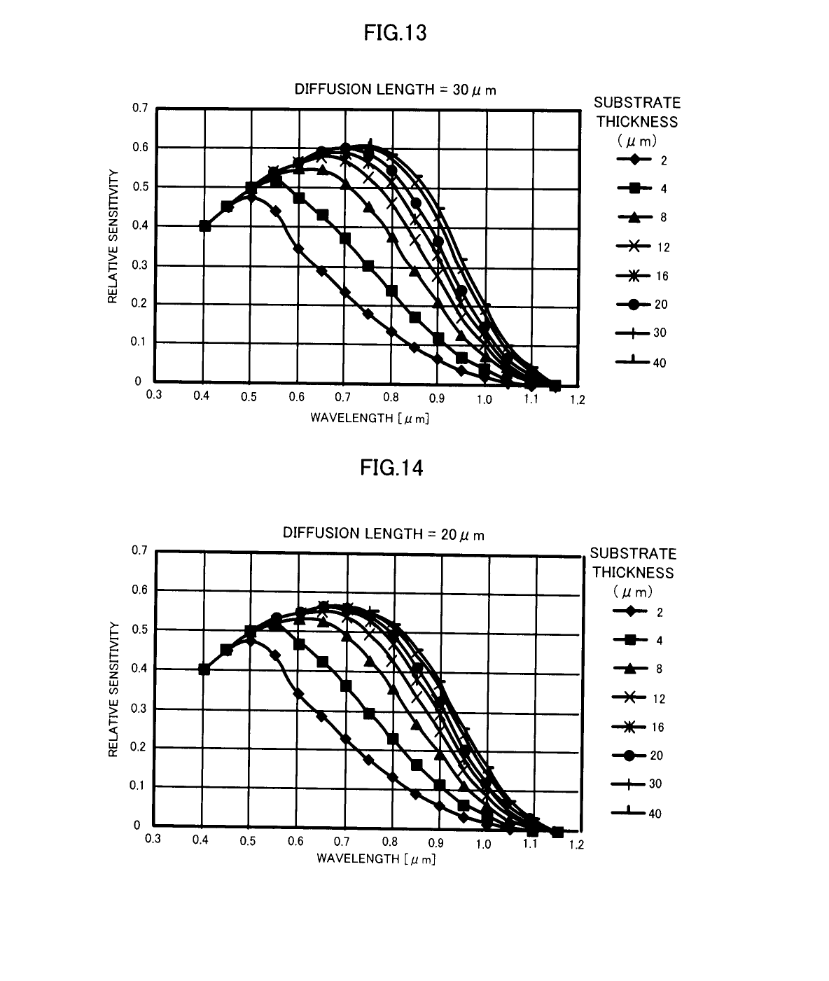

FIG. 13 is a simulation result of the relationship between the relative sensitivity of a conventional solid-state imaging device and the wavelength of light incident on the device when the diffusion length of carriers is 30 μm by thickness (=2 μm, 4 μm, 8 μm, 12 μm, 16 μm, 20 μm, 30 μm, 40 μm) of the semiconductor substrate and the horizontal axis of FIG. 13 represents the wavelength of incident light and the vertical axis thereof represents the relative sensitivity of the device.

As shown in FIG. 13, the relative sensitivity of the conventional solid-state imaging device increases with an increasing thickness of the semiconductor substrate and the peak sensitivity of the conventional solid-state imaging device moves to a longer wavelength side with an increasing thickness of the semiconductor substrate.

In FIG. 13, the relative sensitivity of the conventional solid-state imaging device in the wavelength band (0.4 to 0.7 μm) of the visible light when the thickness of the semiconductor substrate is 2 μm, 4 μm, 8 μm, or 12 μm (when no carrier is generated if the depth is deeper) makes a big difference with respect to a change in thickness of the semiconductor substrate. In contrast, the relative sensitivity of the conventional solid-state imaging device in the wavelength band of the visible light when the thickness of the semiconductor substrate is 16 μm, 20 μm, 30 μm, or 40 μm makes almost no difference with respect to a change in thickness of the semiconductor substrate. The result indicates that the visible light is photoelectrically converted mainly near the surface of the semiconductor substrate.

However, even if the thickness of the semiconductor substrate is 16 μm, 20 μm, 30 μm, or 40 μm, the relative sensitivity of the conventional solid-state imaging device in the wavelength band (0.8 μm or more) of infrared rays makes a slight difference with respect to a change in thickness of the semiconductor substrate and the relative sensitivity increases with an increasing thickness of the semiconductor substrate. The result indicates that infrared rays are photoelectrically converted mainly in a deep portion of the semiconductor substrate. However, carriers generated in a deeper portion have a higher probability of disappearance by recombination. Therefore, the relative sensitivity of the conventional solid-state imaging device in the wavelength band (0.8 μm or more) of infrared rays is only slightly affected by the thickness of the semiconductor substrate.

FIG. 14 is a simulation result of the relationship between the relative sensitivity of a conventional solid-state imaging device and the wavelength of light incident on the device when the diffusion length of carriers is 20 μm by thickness (=2 μm, 4 μm, 8 μm, 12 μm, 16 μm, 20 μm, 30 μm, 40 μm) of the semiconductor substrate and the horizontal axis of FIG. 14 represents the wavelength of incident light and the vertical axis thereof represents the relative sensitivity of the device.

As shown in FIG. 14, wavelength dependence of the relative sensitivity of the conventional solid-state imaging device when the diffusion length of carriers is 20 μm results in close matching with the wavelength dependence of the relative sensitivity of the solid-state imaging device shown in FIG. 13.

In all wavelength bands, however, the relative sensitivity of the conventional solid-state imaging device when the diffusion length of carriers is 20 μm is lower than the relative sensitivity of the conventional solid-state imaging device when the diffusion length of carriers is 30 μm (FIG. 13). This result indicates that if the diffusion length of carriers is short, carriers generated in the semiconductor substrate are probabilistically more likely to disappear due to recombination and have more difficulty in reaching the photodiode.

Further, when the thickness of the semiconductor substrate is 16 μm, 20 μm, 30 μm, or 40 μm, the relative sensitivity of the conventional solid-state imaging device in the wavelength band (0.8 μm or more) of infrared rays when the diffusion length of carriers is 20 μm is less likely to be affected by the thickness of the semiconductor substrate than the relative sensitivity of the conventional solid-state imaging device when the diffusion length of carriers is 30 μm. This can also be considered to result from a shorter diffusion length of carriers.

Next, receiving sensitivity of a solid-state imaging device according to the present embodiment when the diffusion length of carriers is 30 μm or 20 μm is simulated.

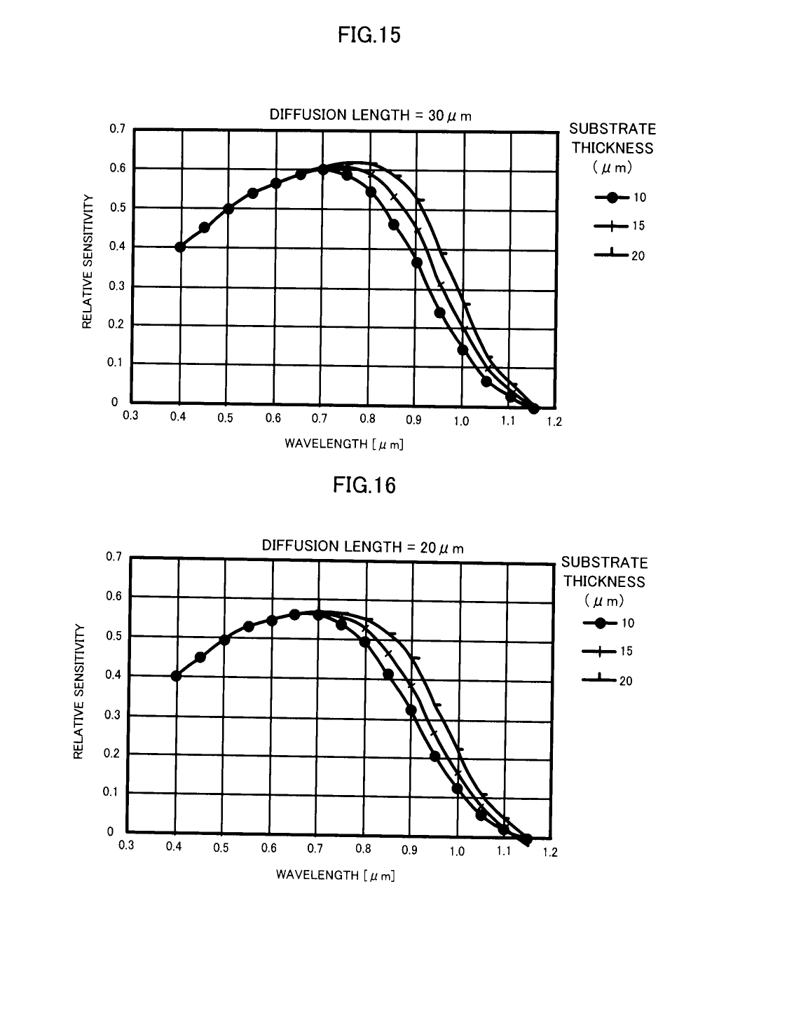

FIG. 15 is a simulation result of the relationship between the relative sensitivity of a solid-state imaging device according to the present embodiment and the wavelength of light incident on the device when the diffusion length of carriers is 30 μm by thickness (=10 μm, 15 μm, 20 μm) of the semiconductor substrate and the horizontal axis of FIG. 15 represents the wavelength of incident light and the vertical axis thereof represents the relative sensitivity of the device.

The semiconductor substrate 13 according to the present embodiment has a reflection portion that reflects infrared rays on the back surface thereof. Thus, the thickness of the semiconductor substrate 13 in the solid-state imaging device 10 according to the present embodiment is substantially half the thickness of the semiconductor substrate in a conventional solid-state imaging device. That is, the thicknesses 10 μm, 15 μm, 20 μm of the semiconductor substrate 13 in the solid-state imaging device 10 according to the present embodiment are substantially equal to the thicknesses 20 μm, 30 μm, 40 μm of the semiconductor substrate in a conventional solid-state imaging device respectively.

As shown in FIG. 15, the relative sensitivity of the solid-state imaging device according to the present embodiment increases with an increasing thickness of the semiconductor substrate and the peak sensitivity of the solid-state imaging device moves to a longer wavelength side with an increasing thickness of the semiconductor substrate. As shown in FIG. 13, this trend is similar to the trend of the relative sensitivity of a conventional solid-state imaging device.

In FIG. 15, the relative sensitivity of the solid-state imaging device according to the present embodiment in the wavelength band (0.8 μm or more) of infrared rays is higher than the relative sensitivity of the conventional solid-state imaging device in the same wavelength band (FIG. 13) and a sensitivity difference increases with respect to a change in thickness of the semiconductor substrate.

For example, while the relative sensitivity of the solid-state imaging device according to the present embodiment at wavelength 1.0 μm is about 0.26 when the thickness of the semiconductor substrate is 20 μm (that is, the substantial thickness 40 μm), the relative sensitivity of the conventional solid-state imaging device at the same wavelength is, as shown in FIG. 13, about 0.2 when the thickness of the semiconductor substrate is 40 μm. Also, while a sensitivity difference of the solid-state imaging device according to the present embodiment at wavelength 1.0 μm is about 1.0 with respect to a change of 10 μm (that is, substantially a change of 20 μm) in thickness of the semiconductor substrate, a sensitivity difference of the conventional solid-state imaging device at the same wavelength is, as shown in FIG. 13, about 0.5 with respect to a change of 20 μm in thickness of the semiconductor substrate.

This result indicates that the solid-state imaging device 10 according to the present embodiment reflects most infrared rays by the reflection portion and makes photoelectric conversion thereof near the surface of the semiconductor substrate 13.

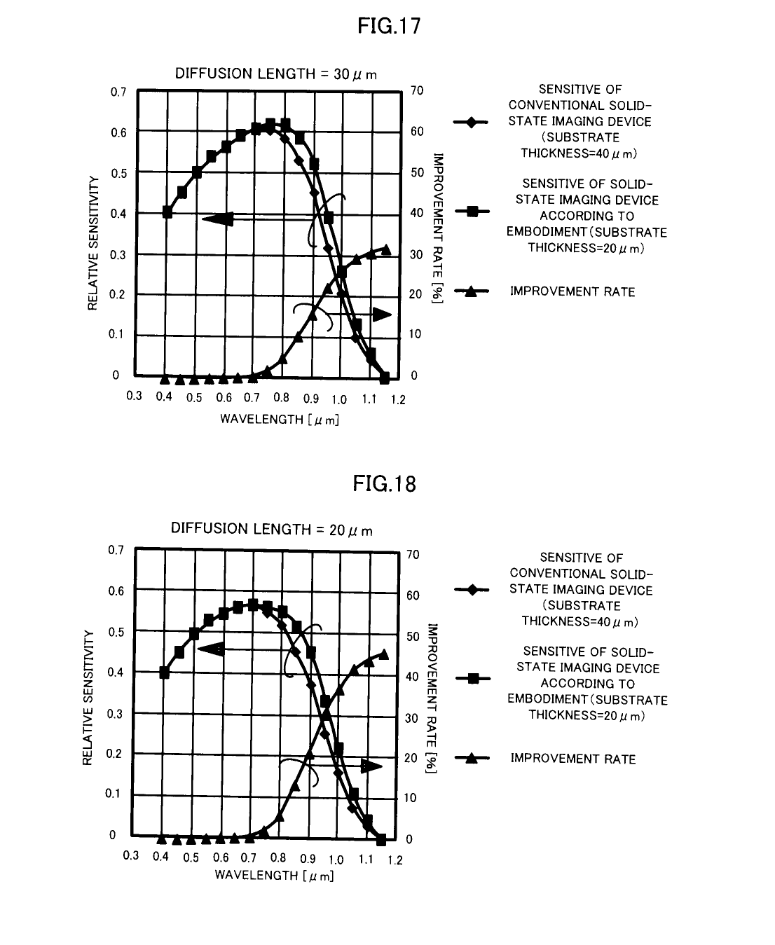

FIG. 16 is a simulation result of the relationship between the relative sensitivity of a solid-state imaging device according to the present embodiment and the wavelength of light incident on the device when the diffusion length of carriers is 20 μm by thickness (=10 μm, 15 μm, 20 μm) of the semiconductor substrate and the horizontal axis of FIG. 16 represents the wavelength of incident light and the vertical axis thereof represents the relative sensitivity of the device.

As shown in FIG. 16, wavelength dependence of the relative sensitivity of the solid-state imaging device according to the present embodiment when the diffusion length of carriers is 20 μm results in a substantially similar trend of the wavelength dependence of the relative sensitivity of the solid-state imaging device shown in FIG. 15. That is, the relative sensitivity of the solid-state imaging device according to the present embodiment in the wavelength band (0.8 μm or more) of infrared rays is higher than the relative sensitivity of the conventional solid-state imaging device in the same wavelength band (FIG. 14) and a sensitivity difference increases with respect to a change in thickness of the semiconductor substrate.

For example, while the relative sensitivity of the solid-state imaging device according to the present embodiment at wavelength 1.0 μm is about 0.23 when the thickness of the semiconductor substrate is 20 μm (that is, the substantial thickness 40 μm), the relative sensitivity of the conventional solid-state imaging device at the same wavelength is, as shown in FIG. 14, about 0.16 when the thickness of the semiconductor substrate is 40 μm. Also, while a sensitivity difference of the solid-state imaging device according to the present embodiment at wavelength 1.0 μm is about 1.0 with respect to a change of 10 μm (that is, substantially a change of 20 μm) in thickness of the semiconductor substrate, a sensitivity difference of the conventional solid-state imaging device at the same wavelength is, as shown in FIG. 14, about 0.4 with respect to a change of 20 μm in thickness of the semiconductor substrate.

This result also indicates that the solid-state imaging device 10 according to the present embodiment reflects most infrared rays by the reflection portion and makes photoelectric conversion thereof near the surface of the semiconductor substrate 13.

FIG. 17 is a graph comparing and showing the relative sensitivity of the conventional solid-state imaging device and the relative sensitivity of the solid-state imaging device according to the present embodiment when the diffusion length is 30 μm and the horizontal axis of FIG. 17 represents the wavelength of incident light and the vertical axis thereof represents the relative sensitivity of the solid-state imaging device. In FIG. 17, an improvement rate of the relative sensitivity of the solid-state imaging device according to the present embodiment with respect to the relative sensitivity of the conventional solid-state imaging device is also shown. Incidentally, in FIG. 17, the thickness of the semiconductor substrate included in the conventional solid-state imaging device is 40 μm and the thickness of the semiconductor substrate included in the solid-state imaging device according to the present embodiment is 20 μm.

As is clear from FIG. 17, the solid-state imaging device 10 according to the present embodiment has improved relative sensitivity for infrared rays when compared with the conventional solid-state imaging device. The improvement rate of relative sensitivity for infrared rays having the wavelength of 0.8 μm or more is about 5% to 30%.

FIG. 18 is a graph comparing and showing the relative sensitivity of the conventional solid-state imaging device and the relative sensitivity of the solid-state imaging device according to the present embodiment when the diffusion length is 20 μm and the horizontal axis of FIG. 18 represents the wavelength of incident light and the vertical axis thereof represents the relative sensitivity of the solid-state imaging device. In FIG. 18, an improvement rate of the relative sensitivity of the solid-state imaging device according to the present embodiment with respect to the relative sensitivity of the conventional solid-state imaging device is also shown. Incidentally, in FIG. 18, the thickness of the semiconductor substrate included in the conventional solid-state imaging device is 40 μm and the thickness of the semiconductor substrate included in the solid-state imaging device according to the present embodiment is 20 μm.

As is clear from FIG. 18, the solid-state imaging device 10 according to the present embodiment has improved relative sensitivity for infrared rays when compared with the conventional solid-state imaging device. The improvement rate of receiving sensitivity for infrared rays having the wavelength of 0.8 μm or more is about 5% to 45%.

According to a solid-state imaging device and a method for manufacturing a solid-state imaging device according to the present embodiment, as described above, the semiconductor substrate 13 is thinned to such an extent that most incident infrared rays are reflected by a reflector. Therefore, according to the solid-state imaging device 10 and the method for manufacturing a solid-state imaging device according to the present embodiment, compared with a conventional solid-state imaging device, carriers can be generated in a region closer to the surface of the semiconductor substrate 13. Accordingly, disappearance of carriers due to recombination before the photodiode is reached can be limited. Therefore, carriers can be collected in the photodiode more easily than the conventional solid-state imaging device. Therefore, according to the solid-state imaging device 10 and the method for manufacturing a solid-state imaging device according to the present embodiment, compared with the conventional solid-state imaging device, receiving sensitivity for infrared rays can be improved. This is also clear from the above simulation result.

Further, according to the solid-state imaging device 10 and the method for manufacturing a solid-state imaging device according to the present embodiment, compared with the conventional solid-state imaging device, carriers can be generated in a region closer to the photodiode. Thus, generated carriers can be caused to reach a predetermined photodiode. Therefore, according to the solid-state imaging device 10 and the method for manufacturing a solid-state imaging device according to the present embodiment, compared with the conventional solid-state imaging device, resolution can be improved.

### Second Embodiment

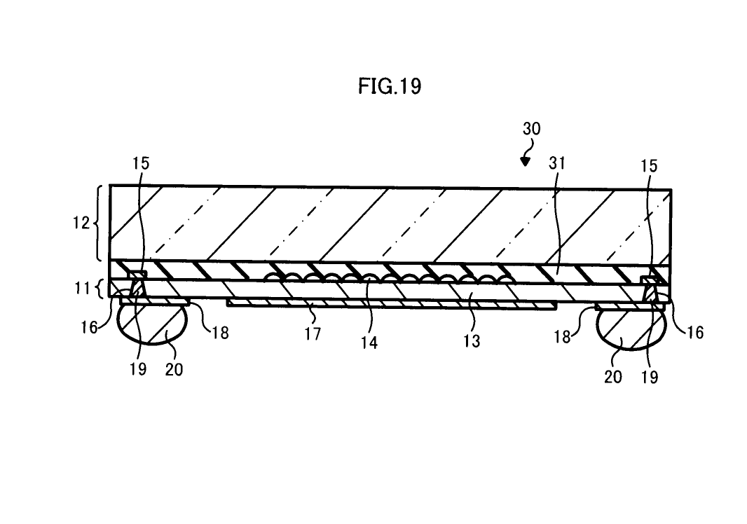

FIG. 19 is a sectional view showing a solid-state imaging device according to the second embodiment and corresponding to FIG. 1. As shown in FIG. 19, compared with the solid-state imaging device 10 according to the first embodiment, a solid-state imaging device 30 according to the present embodiment has a different structure of an adhesive 31.

That is, as shown in FIG. 19, the adhesive 31 is formed on the entire surface on the front surface of the semiconductor substrate 13 in the solid-state imaging device 30 according to the second embodiment. The transparent member 12 is fixed to the semiconductor substrate 13 via the adhesive 31.

The adhesive 31 in this case needs to be an adhesive having transparency because incident light is incident on a photosensitive region of the semiconductor substrate 13 via the transparent member 12 and the adhesive 31.

The shape of the microlens 14 also needs to be appropriately designed by considering a difference of refractive indexes of the microlens 14 and the adhesive.

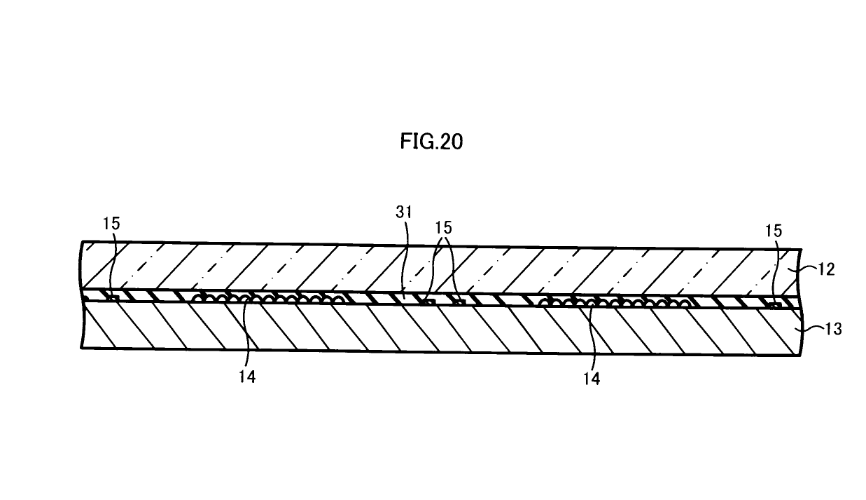

Next, the method for manufacturing the solid-state imaging device 30 according to the second embodiment will be described. Compared with the method for manufacturing the solid-state imaging device 10 according to the first embodiment, the method for manufacturing the solid-state imaging device 30 is different in the process in which the wafer 12 having transparency is fixed onto the semiconductor wafer 13. This process will be described below with reference to FIG. 20.

FIG. 20 is a sectional view illustrating the method for manufacturing the solid-state imaging device 30 according to the second embodiment. As shown in FIG. 20, in the method for manufacturing the solid-state imaging device 30 according to the second embodiment, the process of fixing the wafer 12 having transparency includes forming the adhesive 31 having transparency on the entire surface on the front surface of the semiconductor substrate 13 and fixing the wafer 12 having transparency via the adhesive 31.

All subsequent processes are the same as in the method for manufacturing the solid-state imaging device 10 according to the first embodiment and thus, the description thereof is omitted.

Also according to the solid-state imaging device 30 and the method for manufacturing a solid-state imaging device according to the present embodiment, as described above, the semiconductor substrate 13 is thinned to such an extent that most incident infrared rays are reflected by a reflection portion. Therefore, for the same reason as in the first embodiment, receiving sensitivity for infrared rays can be improved compared with the conventional solid-state imaging device and also resolution can be improved compared with the conventional solid-state imaging device.

Further, according to the solid-state imaging device 30 and the method for manufacturing a solid-state imaging device according to the present embodiment, the adhesive 31 is formed on the entire surface on the front surface of the semiconductor substrate 13 and therefore, the thickness of the semiconductor substrate 13 can be made more uniform.

That is, if, like the solid-state imaging device 10 according to the first embodiment, there is the hollow region 22 on the semiconductor substrate 13, the semiconductor substrate 13 is deflected like being pushed into the hollow region 22 during polishing in the process in which the back surface of the semiconductor substrate 13 is polished and the thickness of the semiconductor substrate 13 after polishing may be non-uniform. If the thickness of the semiconductor substrate 13 is non-uniform, actual receiving sensitivity for infrared rays is different from designed predetermined receiving sensitivity. If, like the solid-state imaging device 30 according to the second embodiment, there is no hollow region on the semiconductor substrate 13, deflection of the semiconductor substrate 13 during polishing can be limited. Therefore, the thickness of the semiconductor substrate 13 can be made uniform. Accordingly, shifts of actual receiving sensitivity for infrared rays from designed predetermined receiving sensitivity can be limited.

The preferred thickness of the semiconductor substrate in a solid-state imaging device according to the above embodiments will be described with reference to FIG. 21. FIG. 21 is a graph showing the relationship between the relative sensitivity and the thickness of the semiconductor substrate in the solid-state imaging device according to the present embodiment when the diffusion length is 30 μm by wavelength of light incident on the device. The wavelength of light is set to 0.70 μm, 0.75 μm, 0.80 μm, 0.85 μm, 0.90 μm, 0.95 μm, 1.00 μm, and 1.05 μm in the range of 0.7 μm to 1.05 μm in the near infrared region subsequent to the visual light region (0.4 to 0.7 μm).

It is clear from FIG. 21 that sensitivity declines when the thickness of the semiconductor substrate becomes less than 20 μm. This can be considered to result from a narrower photoelectric conversion region in the near infrared region.

It is also clear from FIG. 21 that the sensitivity is saturated when the thickness of the semiconductor substrate becomes more than 50 μm.

This trend is the same when the diffusion length is 20 μm and 40 μm.

A charge generated in a deep region diffuses isotropically to flow into the photodiode on the substrate surface. Therefore, the isotropically diffused charge is leaked into adjacent pixels. This phenomenon causes degradation in resolution of a solid-state imaging device. If the thickness of the semiconductor substrate is 50 μm, the depth of the photoelectric conversion region is smaller than 50 μm. However, from the perspective of the resolution, there is no advantage of increasing the thickness of the semiconductor substrate to 50 μm or more in which the sensitivity is saturated.

The trend of relationship between the thickness of the semiconductor substrate and the relative sensitivity is the same when the diffusion length is 20 μm or 40 μm.

From the above perspective, the thickness of the semiconductor substrate is preferably about 20 to 50 μm.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a semiconductor substrate having a photosensitive region including a photodiode on a front surface and a back surface polished by mirror finish;
a reflector formed on the back surface of the semiconductor substrate to reflect infrared rays incident on the photosensitive region; and
an external electrode electrically connected to the photosensitive region.

2. The solid-state imaging device according to claim 1, further comprising:
an adhesive formed on the front surface of the semiconductor substrate; and
a transparent member formed on the semiconductor substrate via the adhesive.

3. The solid-state imaging device according to claim 2, wherein the adhesive is formed around the photosensitive region on the front surface of the semiconductor substrate.

4. The solid-state imaging device according to claim 2, wherein the adhesive is formed on an entire surface on the front surface of the semiconductor substrate including the photosensitive region.

5. The solid-state imaging device according to claim 1, further comprising:
an electric conductor formed inside a through hole passing through the semiconductor substrate and electrically connected to the photosensitive region; and
a wire arranged around the reflector on the back surface of the semiconductor substrate and formed so as to be connected to the electric conductor, wherein the external electrode is formed on the wire.

6. The solid-state imaging device according to claim 5, wherein the reflector, the electric conductor, and the wire are formed of a same material.

7. The solid-state imaging device according to claim 6, wherein the reflector, the electric conductor, and the wire are formed of copper.

8. The solid-state imaging device according to claim 1, wherein the infrared rays has a wavelength of 0.7 μm or more and 1.05 μm or less.

9. The solid-state imaging device according to claim 8, wherein the semiconductor substrate has a thickness of 20 μm or more and 50 μm or less.

10. The solid-state imaging device according to claim 9, wherein the semiconductor substrate is a silicon substrate in which carriers generated by the infrared rays being received has a diffusion length of 20 μm or more and 40 μm or less.

11. A method for manufacturing a solid-state imaging device, comprising:
thinning a semiconductor substrate having a photosensitive region including a photodiode on a front surface from a back surface and polishing the back surface of the semiconductor substrate by mirror finish;
forming a reflector that reflects infrared rays incident on the photosensitive region on the back surface of the thinned semiconductor substrate having the polished back surface; and
forming an external electrode so as to be electrically connected to the photosensitive region.

12. The method for manufacturing a solid-state imaging device according to claim 11, further comprising:
before thinning the semiconductor substrate, forming an adhesive on the front surface of the semiconductor substrate; and
fixing a transparent member onto the semiconductor substrate via the adhesive, wherein the semiconductor substrate is thinned and polished from the back surface while being fixed by the transparent member.

13. The method for manufacturing a solid-state imaging device according to claim 12, wherein the adhesive is formed around the photosensitive region on the front surface of the semiconductor substrate.

14. The method for manufacturing a solid-state imaging device according to claim 12, wherein the adhesive is formed on an entire surface on the front surface of the semiconductor substrate including the photosensitive region.

15. The method for manufacturing a solid-state imaging device according to claim 11, further comprising:
before forming the external electrode, forming a through hole passing through the thinned semiconductor substrate having the polished back surface in a predetermined position of the semiconductor substrate; and
forming an electric conductor inside the through hole of the semiconductor substrate so as to be electrically connected to the photosensitive region and forming a wire around the reflector on the back surface of the semiconductor substrate so as to be connected to the electric conductor, wherein the external electrode is formed on the wire.

16. The method for manufacturing a solid-state imaging device according to claim 15, wherein the reflector, the electric conductor, and the wire are formed in a same step.

17. The method for manufacturing a solid-state imaging device according to claim 16, wherein the reflector, the electric conductor, and the wire are formed of copper.

18. The method for manufacturing a solid-state imaging device according to claim 11, wherein the infrared rays have a wavelength of 0.7 μm or more and 1.05 μm or less.

19. The method for manufacturing a solid-state imaging device according to claim 18, wherein the semiconductor substrate has a thickness of 20 μm or more and 50 μm or less.

20. The method for manufacturing a solid-state imaging device according to claim 19, wherein the semiconductor substrate is a silicon substrate in which carriers generated by the infrared rays being received has a diffusion length of 20 μm or more and 40 μm or less.
